(19) United States
(12) Patent Application Publication
(10) Pub. No.: US 2007/0037340 A1
(43) Pub. Date: Feb. 15, 2007

(54) Fabrication method for fabricating a semiconductor structure and semiconductor structure

(76) Inventors: Albert Birner, Regensburg (DE); Andreas Weber, Dresden (DE); Rolf Weis, Dresden (DE)

Correspondence Address: JENKINS, WILSON, TAYLOR & HUNT, P. A., 3100 TOWER BLVD, SUITE 1200, DURHAM, NC, 27707, US

(21) Appl. No.: 11/477,577

(22) Filed: Jun. 29, 2006

(30) Foreign Application Priority Data
Aug. 9, 2005 (DE) 102005037566.9

(51) Int. Cl. H01L 21/8238

(52) U.S. Cl. 438/218

(57) ABSTRACT

In a method for fabricating a semiconductor structure a semiconductor substrate comprising an active region with an uncovered top side is provided, at least one STI trench adjoining the active region is formed, and an STI divot is formed in the insulating filling. The at least one STI trench comprises an insulating filling extending to above the top side of the active region and the divot adjoins the active region and uncovers an edge of the uncovered top side of the active region. A hydrogen termination of the uncovered top side of the active region is formed and a heat treatment in a hydrogen atmosphere is carried out in order to form a rounding from the edge of the active region in such a way that the top side of the active region continuously merges into the STI divot.

### BACKGROUND OF THE INVENTION

The present invention relates to a method for fabricating a semiconductor structure and a semiconductor structure.

An STI divot at an edge of an active zone of a transistor device impairs the controllability of setting the threshold voltage since field strength effects that are difficult to control occur at the edge. On the other hand, a wraparound of the planar gate area by use of STI divots is useful if the transistor's on current that can be achieved is desired to be increased. The depth of such divots and thus the magnitude of this disadvantageous effect have been influenced hitherto by a plurality of successive wet etching steps. A certain edge rounding of the active zone arose in this case as a result of the pull-back of the pad nitride layer, the oxidation of the active zones and possible sacrificial oxide oxidations.

In the case of customary MOS transistor devices, the enclosing of the edge of the transistor device by the gate oxide and the gate conductor is a factor which reduces the threshold voltage at the edge of the transistor device below the threshold voltage in the central region of the channel and thus creates leakage current problems below the threshold voltage. Particularly in the case of transistor devices of DRAM memory devices, excessively low threshold voltages may result in retention time problems on account of leakage currents below the threshold voltage.

Ideally, the threshold voltage of such a transistor device should be identical everywhere to the threshold voltage in the central region of the transistor device.

Published U.S. application for patent No. US 2001/0014513 A1 discloses a method for fabricating a semiconductor structure, in which method STI divots can be avoided. In the case of this known method, a spin-on glass, after the removal of a pad nitride hard mask, is applied to the STI filling and to an oxide layer situated on the top side of the active region. Divots and seams in the STI trenches are thus filled. Afterward, an annealing step is effected in order to densify the spin-on glass layer, and, finally, the structure is planarized as far as the top side of the active region, initially present divots and seams remaining filled with the spin-on glass.

### BRIEF SUMMARY OF THE INVENTION

The idea on which the present invention is based consists in carrying out a heat treatment in a hydrogen atmosphere in order to form a rounding from the edge of the active region in such a way that the top side of the active region merges continuously into the top side of the filling.

According to the invention, only the oxide removal above the active zone influences the depth of the STI divots. The edge rounding is essentially dominated, therefore, by the depth to which the STI oxide is pulled back prior to the hydrogen process and by the temperature of the subsequent H₂ heat treatment process. A better process control of the divots can thereby be achieved.

In an advantageous manner, according to the invention, it is possible to avoid an edge of the active region and therefore an enclosing of such an edge of an active zone by a later gate structure. It furthermore becomes possible to maximize the maximum current in the ON state of a MOS transistor device that is later to be provided there. Consequently, both the radius of curvature at the top side of the active region and the electrically effective divot depth can be set since the process stops in a self-aligning manner, as it were, once the state of lowest energy has been attained.

The two aspects have a positive effect on the variation of the maximum electric field strength over the chip and thereby improve the Vₜ control and accordingly the retention time distribution in the case of a semiconductor memory device fabricated therefrom, for example. In experiments, the additional H₂ step additionally resulted in an increase in the threshold voltage Vₜ by approximately 120 mV in comparison with a conventional method without edge rounding for the same ON current.

In accordance with one preferred embodiment, the gate dielectric layer and a gate conductor layer are formed on the top side with the rounding formed.

In accordance with a further embodiment, the hydrogen termination is performed prior to application of the hydrogen heat treatment in vaporous or liquid HF solution.

The heat treatment in a hydrogen atmosphere may be carried out at a pressure in the range of between 5 and 15 torr, preferably 10 torr, and at a temperature in the range of 750 and 875° C., preferably 825° C.

In a restricted version of the inventive method, two STI trenches adjoining the active region on opposite sides and having a respective insulating filling extending in each case to above the top side of the active region are formed; and in both STI trenches a respective STI divot is formed in the insulating filling, which divot adjoins the active region and uncovers an edge of the uncovered top side of the active region.

In order to form the STI trenches, a pad oxide layer and an overlying pad nitride layer may be formed on the top side and correspondingly patterned, the STI trenches may be formed by means of an etching step using the patterned pad oxide layer and pad nitride layer as a mask, the filling may be formed by means of a deposition process and subsequent polishing-back process as far as the top side of the pad nitride layer, and the STI divot may be formed by progressively removing the pad nitride layer and pad oxide layer.

The active region may be part of a planar MOS transistor or may be part of a recessed-channel array transistor (RCAT).

An exemplary embodiment of the invention is illustrated in the drawings and is explained in more detail in the description below.

### BRIEF DESCRIPTION OF THE SEVERAL VIEWS OF THE DRAWINGS

FIGS. 1A-E are schematic illustrations of successive method stages of a fabrication method of a semiconductor structure as a first embodiment of the present invention.

FIGS. 2A-C are schematic illustrations of successive method stages of a fabrication method of a semiconductor structure as a second embodiment of the present invention.

### DETAILED DESCRIPTION OF THE INVENTION

In the figures, identical reference symbols designate identical or functionally identical component parts.

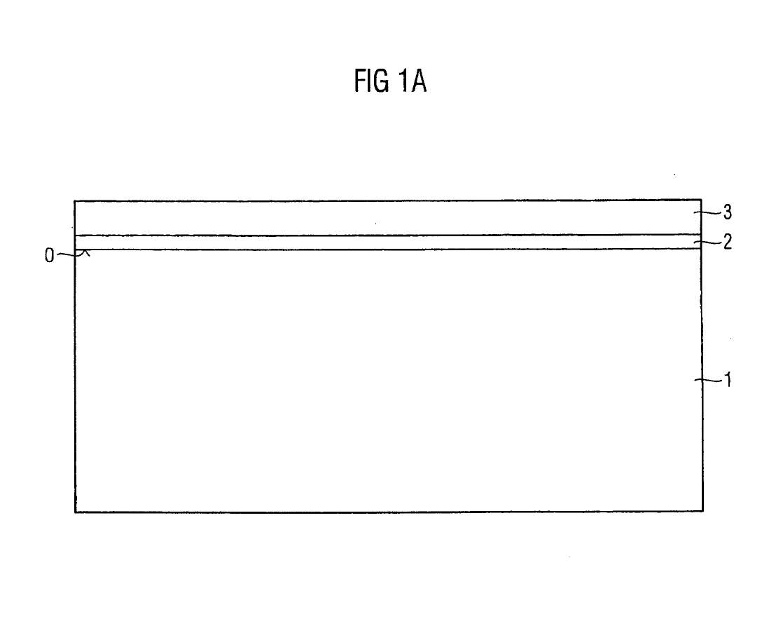

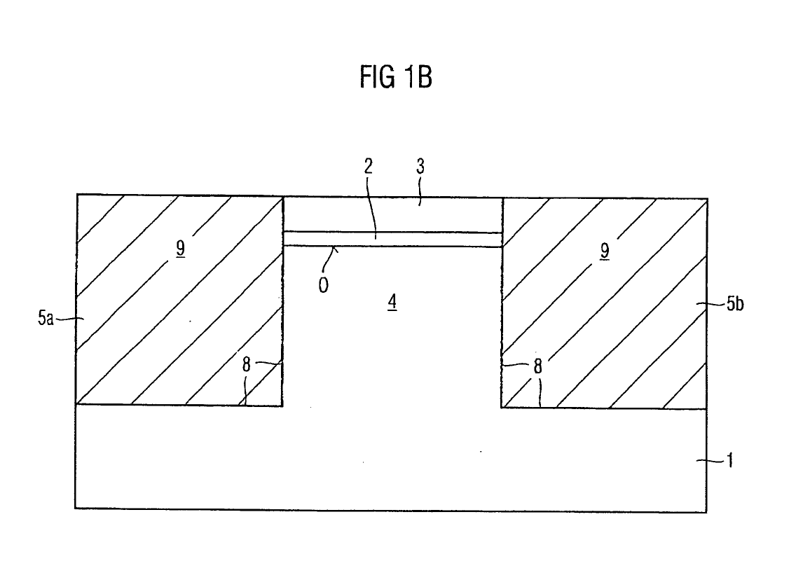

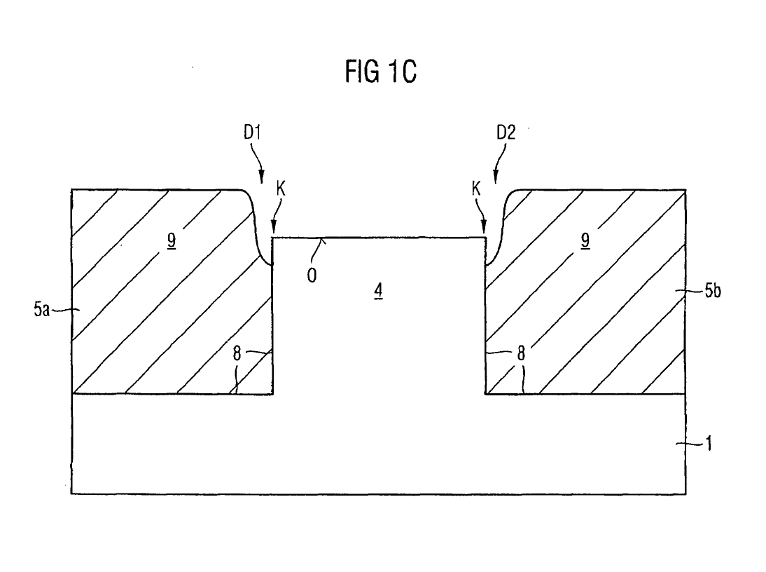

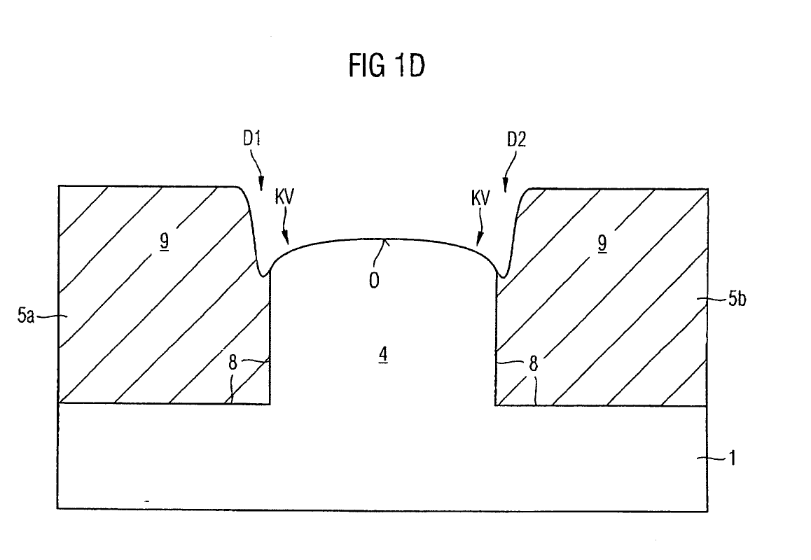

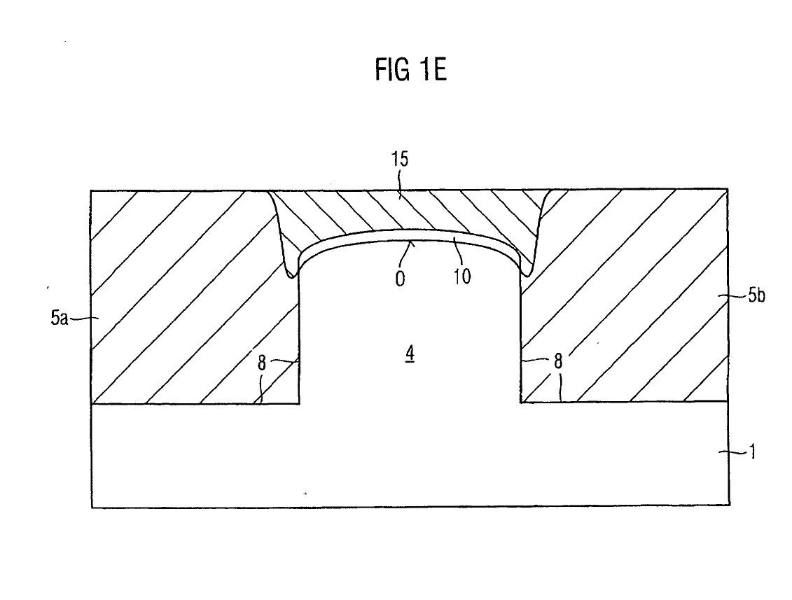

FIGS. 1A-E show schematic illustrations of successive method stages of a fabrication method of a semiconductor structure as a first embodiment of the present invention.

In FIG. 1A, reference symbol 1 designates a silicon semiconductor substrate, to the top side O of which are applied a pad oxide layer 2 and, above the latter, a pad nitride layer 3.

Referring further to FIG. 1B, by means of a method known per se, mask openings (not illustrated) are formed in the pad oxide layer 2 and pad nitride layer 3 and STI trenches 5a, 5b are subsequently etched into the semiconductor substrate 1 with the aid of said mask openings. The walls of the STI trenches 5a, 5b are then provided with a thermal oxide layer 8, and, finally, the STI trenches 5a, 5b are filled with an insulating silicon oxide filling 9 and planarized as far as the top side of the pad nitride layer 3 by means of a CMP process (chemical mechanical polishing). This leads to the structure shown in FIG. 1b, reference symbol 4 representing an active zone for a MOS transistor that is later to be formed.

Referring to FIG. 1C, the pad nitride layer 3 is then firstly removed by means of a corresponding wet etching process. In a further wet etching process, the pad oxide layer 2 is then removed above the active region 4, in which case, due to locally excessively increased wet etching rates, divots D1, D2 form at the edges of the active region 4, in the filling 9, at which the filling 9 of the STI trenches 5a, 5b has been pulled back to below the top side O of the semiconductor substrate in the active region 4 at the edges K thereof.

The width of the active region 4 is typically 90 to 100 nm in the case of present-day technologies, and the depth extent of the divots D1, D2 below the top side O of the active region 4 is typically 15 to 20 nm.

A subsequent process step then involves effecting an H termination of the uncovered top side O of the active region 4 by means of vaporous or by means of liquid HF solution. Oxide islands that have possibly remained on the top side O of the active region 4 are removed in the course of said H termination.

Afterward, it is possible to establish an edge rounding KV of the active region 4 by reshaping the edges K thereof by means of a subsequent heat treatment in an H₂ atmosphere, as shown in FIG. 1D. For this purpose, such a heat treatment step is effected at 10 torr and 875° C. for approximately 1 to 30 seconds. At said pressure of 10 torr hydrogen atmosphere, a temperature range of between 750° C. and 875° C. has proved to be particularly suitable. At higher temperatures, a faceting of the top side O of the active zone 4 or an oxide removal of the oxide filling 9 or silicon removal of the active zone 4 occur in an undesirable manner.

In this case, the topology of the top side O of the active region 4 is altered by rearrangement of silicon atoms until a state of lowest free surface energy has been attained. This state corresponds to an edge rounding KV of the previously present edges K of the top side O of the active region 4. The edge rounding is continuous and likewise merges continuously into the STI divots D1, D2 of the STI trenches 5a, 5b, which finally leads to the process state shown in FIG. 1D. In this case, the silicon of the active zone 4 is as it were pinned at the edge of the oxide filling 9 of the STI trenches 5a, 5b.

By virtue of this edge rounding KV, there are no longer any edges K and thus no wraparound of an edge by a later gate structure, as illustrated in FIG. 1E, in which 10 designates a gate oxide layer on the top side 0 of the active region 4 and in which 15 designates an overlying gate conductor, e.g. made of polysilicon.

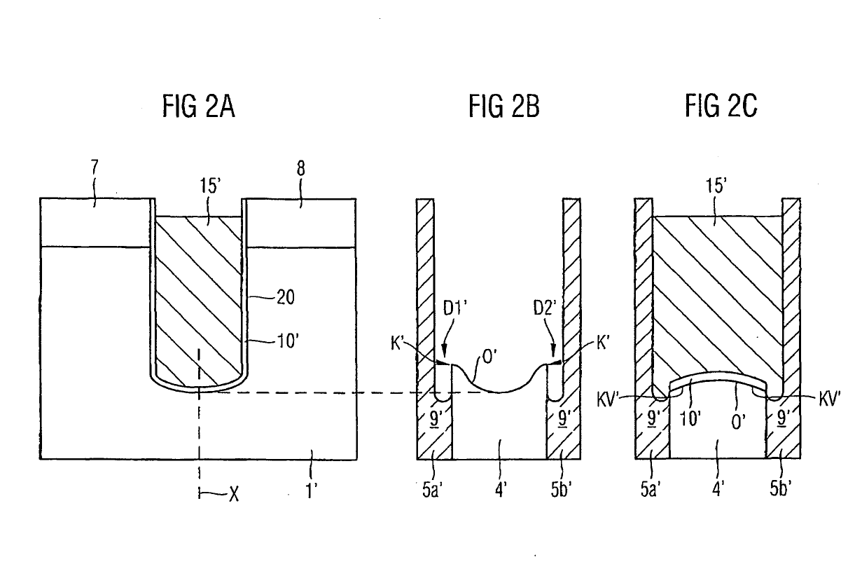

FIGS. 2A-C show schematic illustrations of successive method stages of a fabrication method of a semiconductor structure as an embodiment of the present invention.

The second embodiment in accordance with FIGS. 2A to C involves an RCAT transistor device (RCAT=Recessed Channel Array Transistor), in which a U-shaped channel runs through a silicon semiconductor substrate 1′ along a trench 20 with a gate dielectric 10′ and a gate conductor 15′, as shown in FIG. 2A. The reference symbols 7 and 8 designate a source and drain zone, respectively.

FIG. 2A represents a longitudinal section through an RCAT transistor device of this type, whereas FIGS. 2B and 2C illustrate a cross section along the sectional line X in FIG. 2A.

As can be gathered from FIG. 2B, the active region 4′ is bounded on both sides by a respective STI trench 5a′, 5b′ in the transverse direction. During the fabrication of the trench 20, divots D1′, D2′ form at the edges K′ of the active region 4′.

Following the process state shown in FIG. 2B, the H termination of the top side O′ in a vaporous or liquid HF solution as already described in connection with the first embodiment is then effected in accordance with FIG. 2C. The final step effected is the heat treatment in an H₂ atmosphere at a temperature of between 750° C. and 875° C. and a pressure of 10 torr in order to restructure the previously present edges K′ of the top side O′ of the active region 4′ into an edge rounding KV′, which is pinned at the corresponding corner of the oxide filling 9′ of the STI trenches 5a′, 5b′, which leads to a continuous transition.

Consequently, in the case of this RCAT transistor device too, a wraparound of an edge of an active region 4′ by a gate dielectric or a gate conductor can be avoided, which leads to a better controllability of the threshold voltages Vₜ with a consistently high on current of the transistor.

Although the present invention has been described above on the basis of a preferred exemplary embodiment, it is not restricted thereto, but rather can be modified in diverse ways.

Although in the above exemplary embodiments the edge rounding was provided directly after fabrication of the STI trenches, this is also possible at a later juncture. In such a process sequence, after the removal of the pad oxide layer, numerous further process steps, in particular implantations of wells and so on, would be effected, in which case a sacrificial oxide layer would also be provided on the active region in the meantime. In the case of this alternative embodiment, the rounding would then be carried out directly prior to the formation of the final gate oxide.

Instead of the vaporous or liquid HF termination prior to the H₂ heat treatment step, an H₂ bake step could also be carried out prior to the H₂ heat treatment step, to be precise at a higher temperature than the H₂ heat treatment step. However, such a process flow exhibits poorer controllability since the removal of the oxide islands merges directly into the rounding process. If, therefore, the H₂ bake step is carried out for an excessively long time in this case, undesired faceting effects or oxide or silicon removal effects might already occur early on during the rounding process.

The method described could likewise be carried out using the hydrogen isotope deuterium.

Finally, the present invention is not limited to the transistor structures explained here, but rather can be applied in principle to any desired transistor structures.

What is claimed is:

1. A method for fabricating a semiconductor structure, comprising the steps of:
providing a semiconductor substrate comprising an active region with an uncovered top side;
forming at least one STI trench adjoining said active region; said at least one STI trench comprising an insulating filling extending to above said top side of said active region;
forming an STI divot in said insulating filling; said divot adjoining said active region and uncovering an edge of said uncovered top side of said active region;
forming a hydrogen termination of said uncovered top side of said active region; and
carrying out a heat treatment in a hydrogen atmosphere in order to form a rounding from said edge of said active region in such a way that said top side of said active region continuously merges into said STI divot.

2. The method of claim 1, comprising forming a gate dielectric layer and a gate conductor layer on said top side utilizing said rounding.

3. The method of claim 1, comprising performing said hydrogen termination in a vaporous or liquid HF solution.

4. The method of claim 1, comprising carrying out said heat treatment in a hydrogen atmosphere at a temperature in the range of 750 and 875° C.

5. The method of claim 1, comprising carrying out said heat treatment in a hydrogen atmosphere at a temperature of 825° C.

6. The method of claim 1, comprising carrying out said heat treatment in a hydrogen atmosphere at a pressure of 10 torr and at a temperature in the range of 750 and 875° C.

7. The method of claim 1, comprising carrying out said heat treatment in a hydrogen atmosphere at a pressure of 10 torr and at a temperature of 825° C.

8. The method of claim 1, comprising, in order to form said STI trench, the steps of:
forming and patterning a pad oxide layer and an overlying pad nitride layer on said top side;
etching said STI trench utilizing said patterned pad oxide layer and pad nitride layer as a mask;
forming said filling by means of a deposition process and subsequent polishing-back process as far as the top side of said pad nitride layer; and
forming said STI divot by progressively removing said pad nitride layer and said pad oxide layer.

9. The method of claim 1, wherein said active region is part of a planar MOS transistor or an RCAT transistor.

10. A semiconductor structure comprising:
a semiconductor substrate comprising an active region with an uncovered top side;
at least one STI trench adjoining said active region and comprising an insulating filling extending to above said top side of said active region;
an STI divot in said insulating filling; said STI divot adjoining said active region; and
a rounding of said active region in such a way that said top side of said active region continuously merges into said STI divot.

11. A method for fabricating a semiconductor structure, comprising the steps of:
providing a semiconductor substrate comprising an active region with an uncovered top side;
forming two STI trenches adjoining said active region on opposite sides; each of said two STI trenches comprising a respective insulating filling extending to above said top side of said active region;
forming in each of said STI trenches a respective STI divot, each said divot adjoining said active region and uncovering an edge of said uncovered top side of said active region;
forming a hydrogen termination of said uncovered top side of said active region; and
carrying out a heat treatment in a hydrogen atmosphere in order to form a respective rounding from said edges of said active region in such a way that said top side of said active region continuously merges into said STI divots.

12. The method of claim 11, comprising forming a gate dielectric layer and a gate conductor layer on said top side utilizing said rounding.

13. The method of claim 11, comprising performing said hydrogen termination in a vaporous or liquid HF solution.

14. The method of claim 11, comprising carrying out said heat treatment in a hydrogen atmosphere at a temperature in the range of 750 and 875° C.

15. The method of claim 11, comprising carrying out said heat treatment in a hydrogen atmosphere at a temperature of 825° C.

16. The method of claim 11, comprising carrying out said heat treatment in a hydrogen atmosphere at a pressure of 10 torr and at a temperature in the range of 750 and 875° C.

17. The method of claim 11, comprising carrying out said heat treatment in a hydrogen atmosphere at a pressure of 10 torr and at a temperature of 825° C.

18. The method of claim 11, comprising, in order to form said STI trenches, the steps of:
forming and patterning a pad oxide layer and an overlying pad nitride layer on said top side;
etching said STI trenches utilizing said patterned pad oxide layer and pad nitride layer as a mask;
forming said fillings by means of a deposition process and subsequent polishing-back process as far as the top side of said pad nitride layer; and
forming said STI divots by progressively removing said pad nitride layer and said pad oxide layer.

19. The method of claim 11, wherein said active region is part of a planar MOS transistor or an RCAT transistor.
